(19) United States
(12) Patent Application Publication
(10) Pub. No.: US 2010/0224922 A1
(43) Pub. Date: Sep. 9, 2010

(54) SEMICONDUCTOR DEVICE AND METHOD OF MANUFACTURING THE SAME

(75) Inventor: Takashi SHINHARA, Tokyo (JP)

Correspondence Address: YOUNG & THOMPSON, 209 Madison Street, Suite 500, Alexandria, VA, 22314, US

(73) Assignee: ELPIDA MEMORY, INC., Tokyo (JP)

(21) Appl. No.: 12/717,417

(22) Filed: Mar. 4, 2010

(30) Foreign Application Priority Data
Mar. 5, 2009 (JP) 2009-052296

(51) Int. Cl. H01L 27/108; H01L 21/8242

(52) U.S. Cl. 257/296; 438/591; 257/411; 257/E21.647; 257/E27.097

(57) ABSTRACT

A semiconductor device includes: a first multi-layered structure; a first insulating film over the first multi-layered structure, the first insulating film containing fluorine; and a second insulating film over the first insulating film.

### BACKGROUND OF THE INVENTION

1. Field of the Invention

The present invention relates to a semiconductor device and a method of manufacturing the same. Particularly, the present invention relates to a passivation film covering a multi-layered wiring structure of a semiconductor device and to a method of forming the passivation film.

Priority is claimed on Japanese Patent Application No. 2009-052296, filed Mar. 5, 2009, the content of which is incorporated herein by reference.

2. Description of the Related Art

Recently, various insulating films are used as an inter-layer insulating film or a passivation film included in a semiconductor device having a multi-layered wiring structure. An insulating film having a low dielectric constant, which is called a low-k film, is used as the inter-layer insulating film to reduce capacity between wirings.

Generally, a surface of a semiconductor device is covered by a passivation film in order to prevent a fluid or the like from invading into the semiconductor device. As disclosed in, for example, Japanese Patent Laid-Open Publication No. 2002-252280, a fluorine-containing silicon oxide film is used as the low-k film. Additionally, a silicon nitride film is used as the passivation film.

Generally, dangling bonds on a silicon surface of a semiconductor device cause an increase in leak current. To prevent this, hydrogen termination and fluorine termination of dangling bonds have been proposed. However, hydrogen termination causes the bonds to easily break, resulting in regeneration of dangling bonds.

For this reason, fluorine termination of dangling bonds is preferred since an energy of a fluorine-silicon bond is greater than that of a hydrogen-silicon bond, and the fluorine-silicon bond is more stable than the hydrogen-silicon bond.

As disclosed in the above related art, the fluorine-containing low-k film is used as an inter-layer insulating film. Accordingly, the fluorine included in the low-k film is expected to diffuse toward the silicon surface and therefore terminate dangling bonds.

However, demands for an inter-layer insulating film having a lower dielectric constant has been recently increasing. For this reason, a carbon-containing silicon oxide film rather than a fluorine-containing inter-layer insulating film is used as an inter-layer insulating film. This is because the carbon-containing silicon oxide film has better characteristics than that of fluorine-containing inter-layer insulating film with respect to a dielectric constant or the like. If a carbon-containing silicon oxide film is used as an inter-layer insulating film, fluorine termination of dangling bonds cannot be achieved.

### SUMMARY

In one embodiment, a semiconductor device may include, but is not limited to: a first multi-layered structure; a first insulating film over the first multi-layered structure, the first insulating film containing fluorine; and a second insulating film over the first insulating film.

In another embodiment, a semiconductor device may include, but is not limited to: a substrate; a first multi-layered structure over the substrate; a second multi-layered structure over the first multi-layered structure. The second multi-layered structure includes a fluorine-containing insulating film and a barrier film over the fluorine-containing insulating film.

In still another embodiment, a method of manufacturing a semiconductor device, includes, but is not limited to the following processes. A first multi-layered structure is formed over a substrate. Then, a second multi-layered structure is formed over the first multi-layered structure. The second multi-layered structure includes an insulating film and a barrier film over the insulating film. The insulating film contains fluorine. Then, fluorine is diffused from the insulating film toward the substrate to terminate dangling bonds on the substrate.

Accordingly, dangling bonds on the interfacial surface of the substrate can be efficiently terminated by fluorine diffusing from the fluorine-containing insulating film toward the substrate. Further, the barrier film prevents fluorine from diffusing from the fluorine-containing insulating film toward the barrier film.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a cross-sectional view illustrating a DRAM according to a first embodiment of the present invention;

FIG. 2 is an enlarged view illustrating a support film of the DRAM; and

FIGS. 3-8 are cross-sectional views indicative of a process flow illustrating a method of manufacturing the DRAM.

### DETAILED DESCRIPTION OF THE PREFERRED EMBODIMENTS

The present invention will now be described herein with reference to illustrative embodiments. The accompanying drawings show a semiconductor device and a method of manufacturing the semiconductor device in the embodiments. The size, the thickness, and the like of each illustrated portion might be different from those of each portion of an actual semiconductor device.

Those skilled in the art will recognize that many alternative embodiments can be accomplished using the teachings of the present invention and that the present invention is not limited to the embodiments illustrated herein for explanatory purposes.

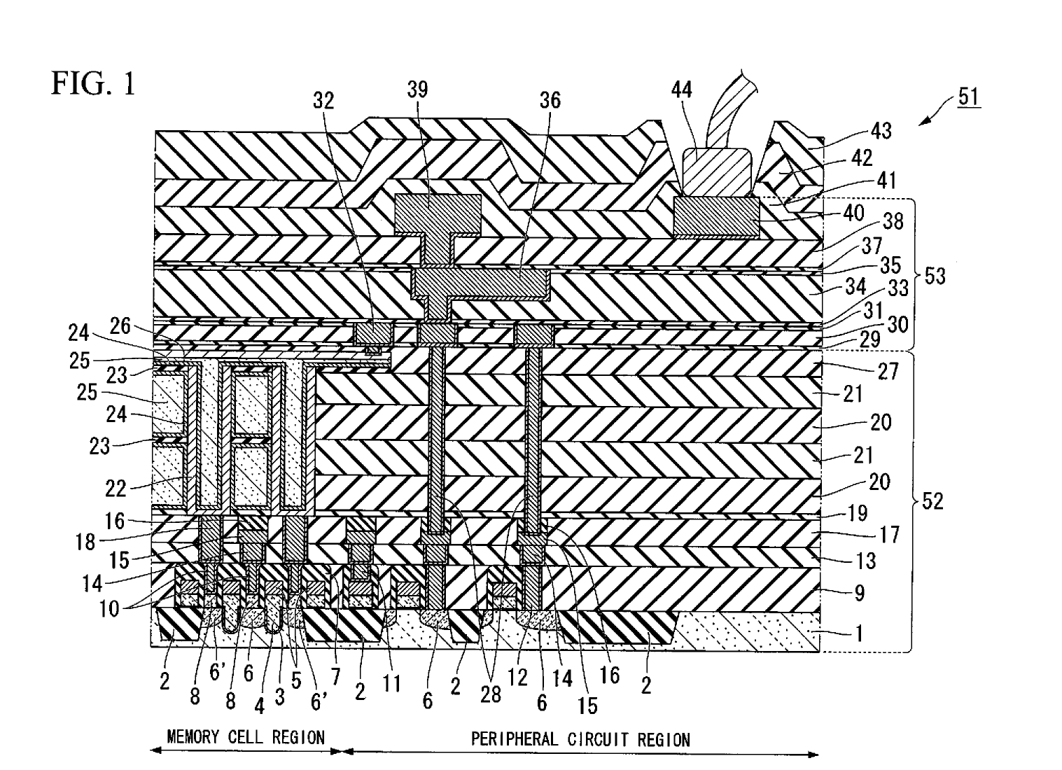

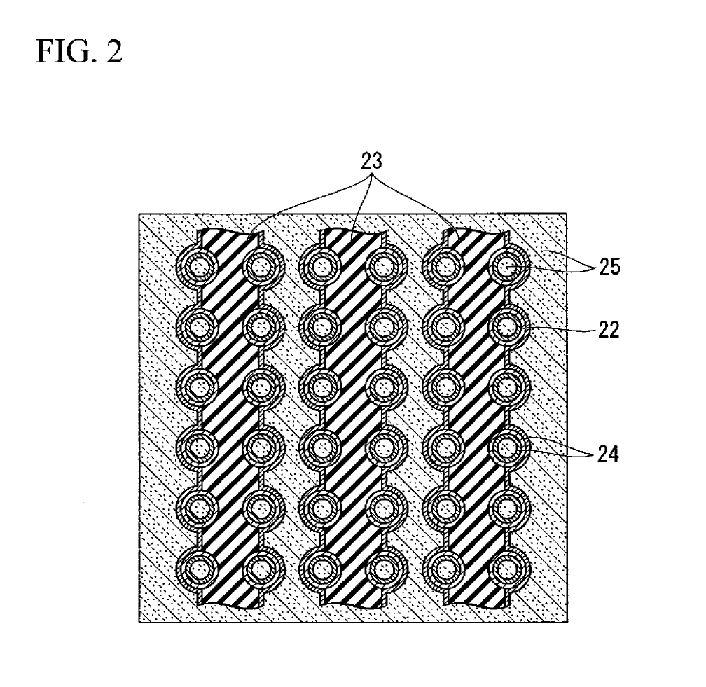

A first embodiment of the present invention explains a case where the present invention is applied to a DRAM (Dynamic Random Access Memory) as a semiconductor device. FIG. 1 is a cross-sectional view illustrating a DRAM (semiconductor device) 51 according to the first embodiment. FIG. 2 is an enlarged view illustrating a support film 23 of the DRAM 51.

As shown in FIG. 1, the DRAM 51 includes a multi-layered wiring structure in which a fluorine-containing insulating film (hereinafter, “intervening film”) 41 is disposed between an uppermost third wiring layer 39 and a passivation film 42 over the third wiring layer 39.

Specifically, the DRAM 51 schematically includes: a semiconductor element layer 52 including a silicon substrate (semiconductor substrate) 1; a multi-layered wiring layer 53 over the semiconductor element layer 52; an intervening film (first insulating film) 41 over the multi-layered wiring layer 53; and a passivation film (second insulating film) 42 over the intervening film 41. The DRAM 51 has a memory cell region and a peripheral cell region.

The semiconductor element layer 52 is a multi-layered structure including a transistor, a capacitor, and the like which are formed over the silicon substrate 1, as shown in FIG. 1. Multiple active regions are defined by an isolation insulating film 2 in the silicon substrate 1. The DRAM 51 has a cell structure in which a memory cell corresponding to 2 bits of data is included in one active region defined by the isolation insulating film 2.

In other words, a basic transistor structure is formed in one active region defined by the isolation insulating film 2 in the memory cell region. The basic structure includes an impurity diffusion region 6 in the center of the active region and two impurity diffusion regions 6′ on both sides of the active region, as shown in FIG. 1. The impurity diffusion region 6 serves as a drain. The impurity diffusion regions 6′ serve as sources.

Two trenches are formed in the active region. A gate electrode 3 covers an inner surface of each trench. A gate electrode is formed in the trench through the gate oxide film 3.

The gate electrode includes a polysilicon film 4 and a tungsten film 5 deposited over the polysilicon film 4. The gate electrode is covered by an insulating film 7. A doped polycrystalline silicon film can be used as the polysilicon film 4. The doped polycrystalline silicon film is formed by doping an impurity into a silicon film formed by a CVD (Chemical Vapor Deposition). Instead of tungsten (W), a tungsten silicide (WSi) or a high melting point metal can be used as the tungsten film 5.

An inter-layer insulating film 9 is formed over the silicon substrate 1 and the isolation insulating film 2 so as to cover the insulating film 7. Inter-layer insulating films 13 and 17 are sequentially deposited over the inter-layer insulating film 9. The inter-layer insulating films 9 and 17 include an SOD (Spin On Dielectrics) film, and have thicknesses of 200 nm and 100 nm, respectively. The inter-layer insulating film 13 includes a CVD film and has a thickness of 100 nm.

The inter-layer insulating film 9 includes an epitaxial layer 8 contacting with the diffusion region 6 or 6′, and a contact 10 over the epitaxial layer 8. A contact 14 is formed over the contact 10 so as to penetrate the inter-layer insulating film 13. The inter-layer insulating film 17 includes a bit line 15 contacting with the contact 14, and an insulating film 16 covering an upper surface of the bit line 15. The diffusion region 6, which will be a drain, is connected to the bit line 15 through the epitaxial layer 8, the contact 10, and the contact 14.

A cylinder stopper film 19 is formed over the entire inter-layer insulating film 17. The cylinder stopper film 19 includes, for example, a nitride silicon film having a thickness of 50 nm formed by low-pressure CVD. A plurality of inter-layer insulating films 20 and 21 are alternately deposited over the cylinder stopper film 19.

The inter-layer insulating film 20 includes, for example, a BPSG (Boro Phospho Silicate Glass) film having a thickness of 500 nm formed by normal-pressure CVD. The inter-layer insulating film 21 includes, for example, an oxide silicon film having a thickness of 550 nm to 700 nm formed by plasma CVD.

A contact 18 is formed over the contact 10 so as to penetrate the inter-layer insulating films 13 and 17. A lower capacity electrode 22 is formed over the contact 18 so as to penetrate the cylinder stopper film 19 and the plurality of inter-layer insulating films 20 and 21. The lower capacity electrode 22 includes a multi-layered structure including a titanium nitride film and a titanium film, which has a thickness of 25 nm.

The diffusion region 6′, which will be a source, is connected to the lower capacity electrode 22 through the epitaxial layer 8, the contact 10, and the contact 18.

The lower capacity electrode 22 has a cylindrical shape as shown in FIG. 1. Support films 23 are formed at middle and top portions of the lower capacity electrode 22 so as to support the adjacent lower capacity electrodes 22. The support film 23 includes a silicon nitride film having a thickness of 100 nm formed by ALD (Atomic Layer Deposition).

As shown in FIG. 2, adjacent lines of the lower capacity electrodes 22 form a pair. None of the lower capacity electrodes 22 is included in more than one pair. The support film 23 is disposed between each line of the lower capacity electrodes 22 forming a pair.

A capacity film 24, a plate electrode support film 25, and a plate electrode 26 are sequentially deposited over the upper support film 23. The capacity film 24 includes, for example, a multi-layered structure having a thickness of 7 nm including an aluminum oxide film and a zirconium oxide film, which are deposited by ALD.

The plate electrode support film 25 includes, for example, a multi-layered structure including a titanium nitride film having a thickness of 10 nm formed by CVD, and a boron-doped silicon-germanium film having a thickness of 150 nm.

The plate electrode 26 includes, for example, a tungsten layer having a thickness of 100 nm formed by spattering. Thus, the lower capacity electrode 22, the capacity film 24, the plate electrode support film 25, and the plate electrode 26 form a capacitor for storing data.

An inter-layer insulating film 27 is formed over the inter-layer insulating film 21 so as to cover the capacitor. The inter-layer insulating film 27 includes a silicon oxide film having a thickness of 40 nm formed by plasma CVD.

Multiple transistors are formed in the semiconductor element layer 52 in the peripheral circuit region. The tungsten film 5 of a transistor is connected to the bit line 15 through the contacts 11. The diffusion region 6 of a transistor is connected to the bit line 15 through the contact 12 and 14. A through hole 28 penetrating the insulating film 16, the cylinder stopper film 19, the inter-layer insulating films 20, 21, and 27 is connected to the bit line 15.

The multi-layered wiring layer 53 is formed over the semiconductor element layer 52, and includes multiple wiring layers and inter-layer insulating films. The present embodiment specifically explains a three-layered wiring structure.

A Cu stopper film 29, a low dielectric constant film 30, and a cap film 31 are sequentially deposited over the inter-layer insulating film 27 included in the semiconductor element layer 52 to form an inter-wiring-layer film. Multiple first wirings 32 are formed so as to penetrate the inter-wiring-layer film. Each of the first wirings 32 is connected to the plate electrode 26 or the through hole 28.

The Cu stopper film 29 includes a silicon carbon nitride (SiCN) film having a thickness of 30 nm formed by plasma CVD. The low dielectric constant film 30 includes fluorine-containing silicon oxide (SiOF) film having a thickness of 110 nm formed by plasma CVD. The cap film 31 includes a silicon oxide film having a thickness of 180 nm formed by plasma CVD. The first wiring 32 includes copper formed by plating.

A Cu stopper film 33, a low dielectric constant film 34, and a cap film 35 are sequentially deposited over the cap film 31 and the first wiring layer 32 to form an inter-wiring-layer film. A second wiring 36 is formed so as to penetrate the inter-wiring-layer film and connect to the first wiring 32. The thicknesses of the Cu stopper film 33, the low dielectric film 34, and the cap film 35 are 80 nm, 570 nm, and 210 nm, respectively. The second wiring 36 includes copper.

A Cu stopper film 37 and an inter-layer insulating film 38 are sequentially deposited over the cap film 35 and the second wiring layer 36 to form an inter-wiring-layer film. A third wiring 39 and a bonding pad 40 are formed over the inter-layer insulating film 38. The third wiring 39 penetrates the inter-wiring-layer film and connects to the second wiring layer 36.

The Cu stopper film 37 includes a silicon carbon nitride (SiCN) film having a thickness of 80 nm. The inter-layer insulating film 38 includes a silicon film having a thickness of 700 nm. The third wiring 39 and the bonding pad 40 include aluminum.

The materials forming the respective inter-wiring-layer films forming the multi-layered wiring layer 53 is not limited to the aforementioned materials. For example, a carbon-containing silicon oxide (SiCO) film having a lower dielectric constant or a normal silicon oxide may be used as the low dielectric films 30 and 34. Additionally, SiOF or SiCO may be used as the inter-layer insulating film 38.

The intervening film 41 is a fluorine-containing insulating film formed over the multi-layered wiring layer 53. Specifically, the intervening film 41 is formed over the inter-layer insulating film 38 so as to cover the third wiring 39 and the bonding pad 40. The intervening film 41 is provided for diffusing fluorine toward the interfacial surface of the silicon substrate 1, and thereby terminating dangling bonds on the interfacial surface of the silicon substrate 1.

The intervening film 41 includes a fluorine-containing silicon oxide (SiOF) film having a thickness of 500 nm formed by CVD. Preferably, a concentration of fluorine included in the intervening film 41 is in the range of 1×10¹⁸ atoms/cm³ to 1×10²° atoms/cm³. If the fluorine concentration is less than 1×10¹⁸ atoms/cm³, fluorine diffusion toward the interfacial surface of the silicon substrate 1 is not sufficient. If the fluorine concentration is greater than 1×10²⁰ atoms/cm³, the intervening film 41 absorbs moisture and is easily peeled from the multi-layered wiring layer 53.

A passivation film 42 is formed over the entire intervening film 41 so as to protect a surface of the multi-layered wiring layer 53 from being externally damaged. In other words, in the DRAM 51 of the present embodiment, the intervening film 41, which is a fluorine-containing insulating film, is formed between the third wiring layer 39 and the passivation film 42.

Preferably, the passivation film 42 is an insulating film working as a barrier against fluorine diffusion, such as a silicon nitride film. For example, a silicon nitride film having a thickness of 550 nm formed by plasma CVD can be used as the passivation film 42.

Since the passivation film 42 works as a barrier against fluorine diffusion during a thermal treatment that will be explained later, fluorine diffuses from the intervening film 41 toward the silicon substrate 1, and thereby terminates dangling bonds on the interfacial surface of the silicon substrate 1. Additionally, the passivation film 42 has a sufficient thickness of 550 nm, thereby preventing fluorine from diffusing from the intervening film 41 towards the passivation film 42 during a long thermal treatment.

Preferably, the passivation film 42 contains hydrogen so that the hydrogen diffuses to the interfacial surface of the silicon substrate 1, and thereby the hydrogen and the fluorine terminate dangling bonds. Preferably, a concentration of hydrogen contained in the passivation film 42 is in the range of 1×10¹⁸ atoms/cm³ to 1×10²⁰ atoms/cm³. If the hydrogen concentration is less than 1×10¹⁸ atoms/cm³, hydrogen diffusion toward the interfacial surface of the silicon substrate 1 is not sufficient. If the fluorine concentration is greater than 1×10²⁰ atoms/cm³, the quality of the passivation film 42 degrades, and therefore the protection performance degrades.

As shown in FIG. 1, a cap film 43 made of a polyimide film is formed over the passivation film 42 so as to protect the semiconductor chip from being externally damaged. Further, the polyimide film has high alpha-ray blocking capability, and therefore prevents the semiconductor chip from radiation damage.

A through hole is formed over the bonding pad 40 so as to penetrate the intervening film 41, the passivation film 42, and the cap film 43. An upper surface of the bonding pad 40 is exposed through the through hole. A bonding wire 44 is connected to the exposed surface of the bonding pad 40. The bonding wire 44 is connected to an external terminal provided in a package, and thus the DRAM 51 is electrically connected to the package.

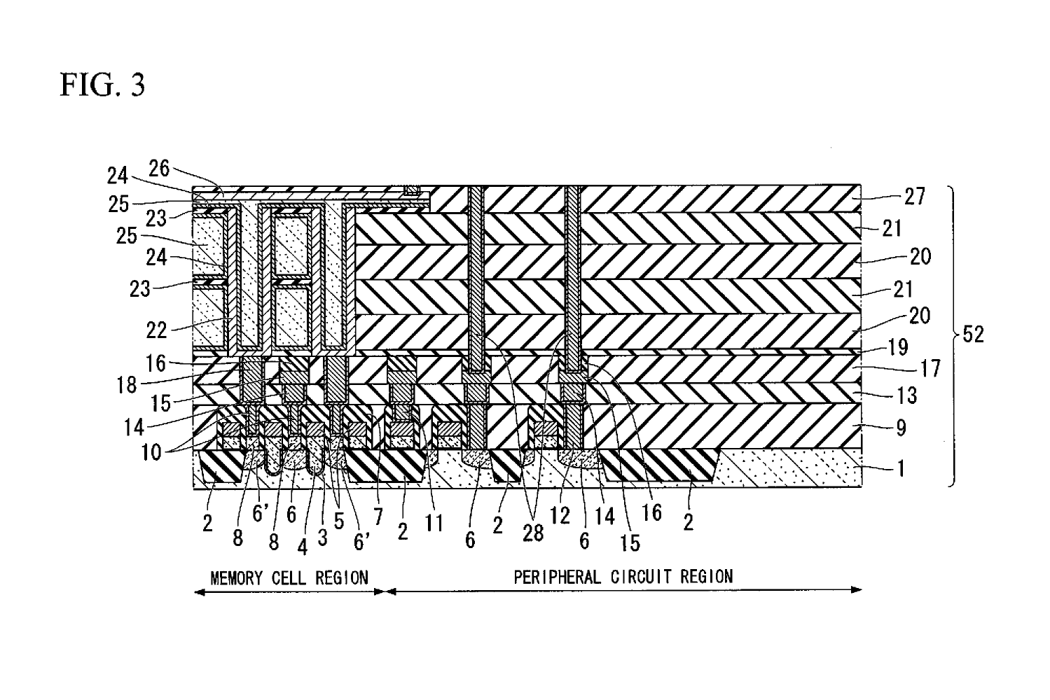

Hereinafter, a method of manufacturing the DRAM (semiconductor device) 51 having the above structure is explained with reference to FIGS. 3 to 8. FIGS. 3-8 are cross-sectional views indicative of a process flow illustrating a method of manufacturing the DRAM.

The method according to the first embodiment schematically includes: a process of forming a multi-layered wiring structure including multiple wiring layers over a silicon substrate (semiconductor substrate); a process of forming a fluorine-containing insulating film (intervening film) over the uppermost wiring layer included in the multi-layered wiring structure; a process of forming a passivation film over the insulating film (intervening film); and a process of carrying out a thermal treatment after forming the insulating film.

Firstly, the semiconductor element layer 52 is formed as shown in FIG. 3. Specifically, recesses for defining an active region on the surface of the silicon substrate 1 are formed. Then, an insulating film is embedded into the recesses to form the isolation insulating films 2. Thus, the isolation insulating films 2 define the active region of the silicon substrate 1.

Then, trenches are formed in the active region in the memory cell region. Then, the gate oxide film 3 is formed by thermal oxidization or the like so as to cover the main surface of the silicon substrate 1 and inner surfaces of the trenches. Then, the polysilicon film 4 and the tungsten film 5 are sequentially deposited in the trenches through the gate oxide film 3. Then, polysilicon film 4 and the tungsten film 5 are patterned to form a gate electrode.

Then, the insulating film 7 is formed by plasma CVD or the like so as to cover the gate electrode. Then, impurity diffusion layers are formed by doping an impurity using the gate electrode and the insulating film 7 as masks, and by carrying out a thermal treatment in a nitrogen atmosphere. The impurity diffusion layers become the diffusion regions 6 and 6′ that will be a drain and a source, respectively. Thus, the basic structure of a transistor is formed.

Then, the inter-layer insulating film (SOD film having a thickness of 200 nm) 9 is formed over the silicon substrate 1 and the isolation insulating film 2 so as to cover the insulating film 7. Then, an upper surface of the inter-layer insulating film 9 is planarized, the epitaxial layer 8 and the contacts 10, 11, and 12 are formed.

Then, the inter-layer insulating film (silicon oxide film having a thickness of 100 nm formed by plasma CVD or the like) 13 is formed over the inter-layer insulating film 9, and then the contact 14 is formed. Then, the bit lines 15 and the insulating film 16 are formed, and then the inter-layer insulating film 17 is formed thereover. Then, an upper surface of the inter-layer insulating film 17 is planarized, and then the contact 18 is formed so as to penetrate the inter-layer insulating films 13 and 17.

Then, the cylinder stopper film (silicon nitride film having a thickness of 50 nm formed by low-pressure CVD) 19 is formed over the inter-layer insulating film 17. Then, the inter-layer insulating film (BPSG film having a thickness of 500 nm formed by normal pressure CVD) 20 and the inter-layer insulating film (silicon oxide film having a thickness of 700 nm formed by plasma CVD) 21 are deposited over the cylinder stopper film 19.

Then, the lower capacity electrode (multi-layered structure including a titanium nitride film and a titanium film, having a thickness of 25 nm formed by CVD) 22 is formed so as to penetrate the cylinder stopper film 19 and the inter-layer insulating films 20 and 21. Then, the support film (silicon nitride film having a thickness of 100 nm formed by ALD) 23 is formed in order to support the adjacent lower capacity electrodes 22.

Then, the inter-layer insulating film (BPSG film having a thickness of 500 nm formed by normal pressure CVD) 20 and the inter-layer insulating film (silicon oxide film having a thickness of 550 nm formed by plasma CVD) 21 are deposited over the inter-layer insulating film 21. Then, the lower capacity electrode (multi-layered structure including a titanium nitride film and a titanium film, having a thickness of 25 nm formed by CVD) 22 is formed so as to penetrate the inter-layer insulating films 20 and 21.

Then, the support film (silicon nitride film having a thickness of 100 nm formed by ALD) 23 is formed in order to support the adjacent lower capacity electrodes 22. Then, the inter-layer insulating films 20 and 21 in the memory cell region are removed by wet etching to expose the lower capacity electrode 22.

Then, the capacity film (multi-layered structure including an aluminum oxide film and a zirconium oxide film, having a thickness of 7 nm formed by ALD) 24, the plate electrode support film (multi-layered structure including a titanium nitride film having a thickness of 7 nm formed by ALD and a boron-doped silicon germanium film having a thickness of 10 nm formed by CVD) 25, and the plate electrode (tungsten film having a thickness of 100 nm formed by spattering) 26 are sequentially formed over the lower capacity electrode 22. Thus, the capacitor is formed.

Then, the inter-layer insulating film (silicon oxide film having a thickness of 400 nm formed by plasma CVD) 27 is formed so as to cover the capacitor. Finally, the through holes 28 are formed in the peripheral circuit region so as to penetrate the insulating film 16, the cylinder stopper film 19, and the inter-layer insulating films 20, 21, and 27. Then, the through holes 29 are connected to the bit lines 15. Thus, the semiconductor element layer 52 including the transistor and the capacitor is formed.

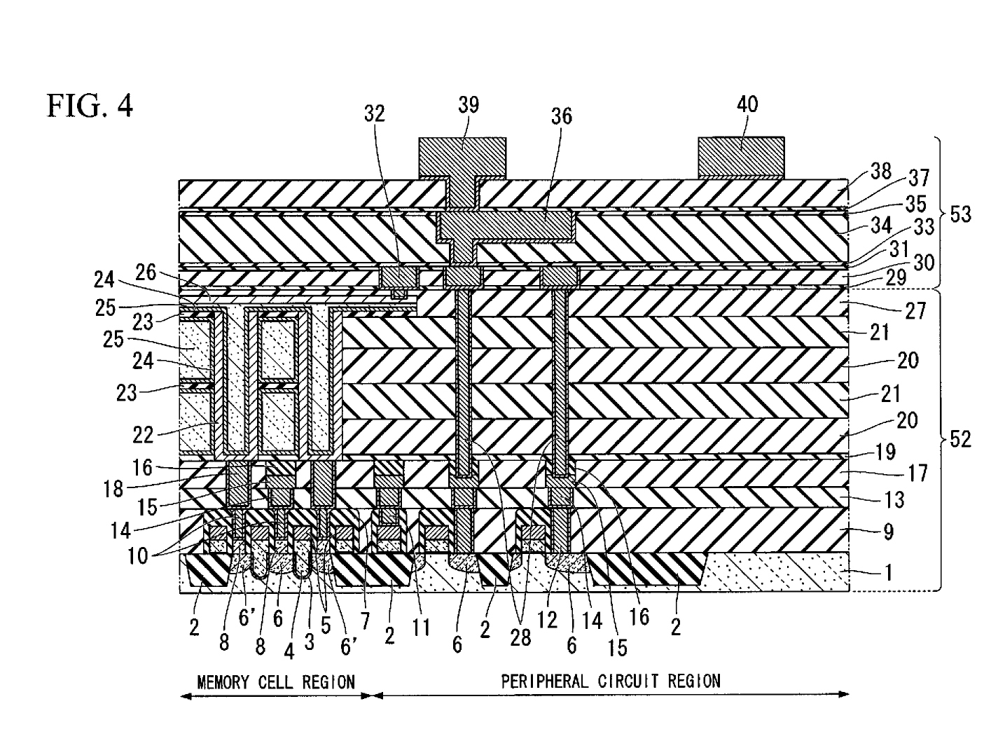

In the process of forming the multi-layered wiring structure, the multi-layered wiring layer 53 is formed over the silicon substrate 1 through the semiconductor element layer 52, as shown in FIG. 4. Specifically, the Cu stopper film (SiCN having a thickness of 30 nm formed by plasma CVD) 29, the low-dielectric film (SiOF having a thickness of 110 nm formed by plasma CVD) 30, and the cap film (silicon oxide film having a thickness of 180 nm formed by plasma CVD) 31 are sequentially formed over the inter-layer insulating film 27 to form the inter-wiring-layer film. Then, multiple first wirings (copper film formed by plating) 32 are formed so as to penetrate the inter-wiring-layer film, and then are connected to the plate electrode 26 or the though holes 28.

Then, the Cu stopper film (SiCN having a thickness of 80 nm) 33, the low-dielectric film (SiOF having a thickness of 570 nm) 34, and the cap film (silicon oxide film having a thickness of 210 nm) 35 are sequentially deposited over the cap film 31 and the first wiring layer 32 to form an inter-wiring-layer film. Then, the second wiring (copper film formed by plating) 36 is formed so as to penetrate the inter-wiring-layer film, and then is connected to the first wiring layer 32.

Then, the Cu stopper film (SiCN having a thickness of 80 nm) 37 and the inter-layer insulating film (silicon oxide film having a thickness of 700 nm) 38 are sequentially deposited over the cap film 35 and the second wiring layer 36 to form an inter-wiring-layer film. Then, the third wiring 39 and the bonding pad 40 (aluminum) are formed over the inter-layer insulating film 38. The third wiring 39 penetrates the inter-wiring-layer film and connects to the second wiring layer 36.

Thus, the multi-layered wiring layer 53 having a three-layered wiring structure is formed. The materials forming the respective inter-wiring-layer films forming the multi-layered wiring layer 53 are not limited to the aforementioned materials. For example, a carbon-containing silicon oxide (SiCO) film having a lower dielectric constant or a normal silicon oxide film may be used for the low-dielectric constant film 30 and 34. Additionally, any one of SiOF and SiCO may be used as the inter-layer insulating film 38.

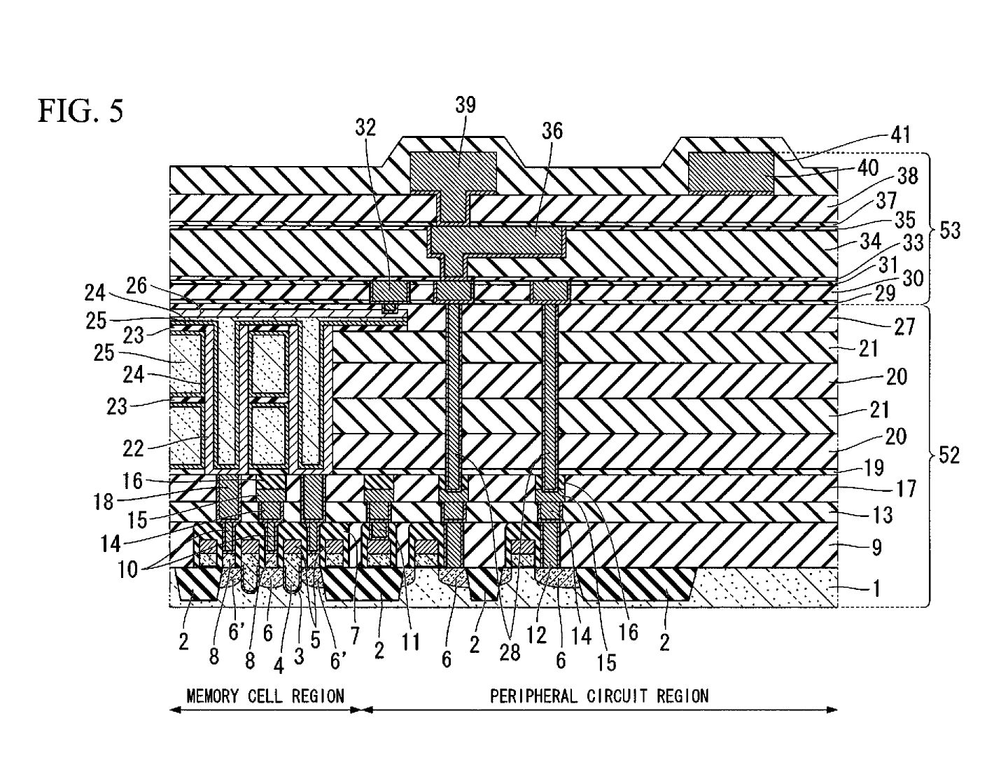

In the process of forming the intervening film 41, the intervening film 41, which is a fluorine-containing insulating film, is formed over the third wiring 39 that is the uppermost layer of the multi-layered wiring layer 53 having the three-layered wiring structure, as shown in FIG. 5.

Specifically, a fluorine-containing silicon oxide film is deposited by CVD over the inter-layer insulating film 38. Thus, the intervening film 41 is formed so as to cover the third wiring 39 and the bonding pad 40. The CVD is carried out under the process condition that a flow amount of silane (SiH₄) is 300 sccm to 1200 sccm, a flow amount of nitrous oxide (N₂O) is 5000 sccm to 20000 sccm, a flow amount of silicon fluoride (SiF₄) is 120 sccm to 500 sccm, and a heating temperature is 400° C. to 450° C. Further, a heating time is controlled so that the thickness of the intervening film 41 becomes 500 nm. Thus, the intervening film 41 having a thickness of 500 nm and a fluorine concentration in the range of 1×10¹⁸ atoms/cm³ to 1×10²⁰ atoms/cm³ is formed.

After the intervening film 41 is formed, a thermal treatment may be carried out. Preferably, the thermal treatment is carried out in a hydrogen atmosphere. A heating temperature is set to, for example, 500° C., which is enough for fluorine included in the intervening film 41 to diffuse toward the interfacial surface of the silicon substrate 1. Additionally, a heating time is set to, for example, 120 minutes, which is enough for fluorine included in the intervening film 41 to diffuse toward the interfacial surface of the silicon substrate 1.

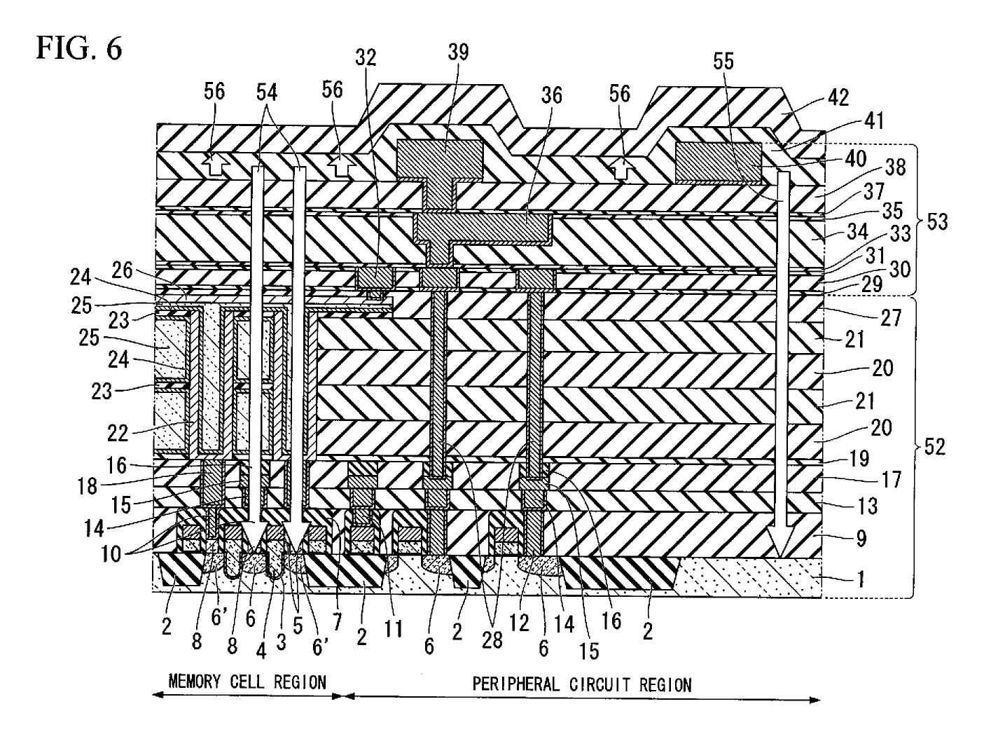

In the process of forming the passivation film, the passivation film 42 is formed over the intervening film 41, as shown in FIG. 6. Specifically, a silicon nitride film is deposited by plasma CVD in the thickness of 550 nm. The plasma CVD is carried out under the process condition that a flow amount of silane (SiH₄) is 700 sccm to 900 sccm, a flow amount of nitrogen (N₂) is 2300 sccm to 2700 sccm, a flow amount of ammonia (NH₃) is 2800 sccm to 3300 sccm, and a heating temperature is 400° C. to 450° C.

Further, a heating time is controlled so that the thickness of the passivation film 42 becomes 550 nm. In this case, the concentration of hydrogen included in the passivation film 42 is in the range of 1×10¹⁸ atoms/cm³ to 1×10²⁰ atoms/cm³. This hydrogen concentration is in proportion to the flow amount of silane and the flow amount of ammonia. However, those two amounts of flow under the process condition are in a trade-off relationship. For this reason, the hydrogen concentration is hard to change. Thus, the passivation film 42 is formed.

In the process of carrying out a thermal treatment, a thermal treatment is carried out after the intervening film 41 and the passivation film 42 are formed, as shown in FIG. 6. Preferably, the thermal treatment is carried out in a hydrogen atmosphere. A heating temperature is set to, for example, 500° C., which is enough for fluorine included in the intervening film 41 to diffuse toward the interfacial surface of the silicon substrate 1.

Additionally, a heating time is set to, for example, 120 minutes, which is enough for fluorine included in the intervening film 41 to diffuse toward the interfacial surface of the silicon substrate 1. If a thermal treatment is not carried out after the intervening film 41 is formed, a thermal treatment is carried out after the passivation film 42 is formed.

In the thermal treatment, fluorine included in the intervening film 41 is required to diffuse toward the interfacial surface of the silicon substrate 1. In this case, fluorine included in the low-dielectric constant films 30 and 34 including an SiOF film diffuses at the same time. On the other hand, it is known that fluorine is difficult to diffuse toward a high-density silicon nitride film.

In the first embodiment, the passivation film 42, the support film 23, and the cylinder stopper film 19 are inter-layer films including a silicon nitride film preventing fluorine diffusion. Hereinafter, fluorine diffusion toward each silicon nitride film is explained.

First, fluorine diffusion toward the support film 23 is explained. As shown in FIG. 2, the support film 23 is disposed between each line of the lower capacity electrodes 22 forming a pair in plane view. For this reason, fluorine can diffuse from the intervening film 41 toward lower layers through regions between the adjacent support films 23, as indicated by an arrow 54 shown in FIG. 6.

Next, fluorine diffusion toward the cylinder stopper film 19 is explained. The cylinder stopper film 19 has though holes at the bottom portions of the lower capacity electrodes 22, as shown in FIG. 6. For this reason, fluorine can diffuse toward lower layers through the through holes, as indicated by the arrow 54 shown in FIG. 6.

Since the cylinder stopper film 19 has a thin thickness of 50 nm, fluorine can diffuse to the interfacial surface of the silicon substrate 1 through the cylinder stopper film 19 by a long thermal treatment for, for example, 120 minutes, as indicated by an arrow 55 shown in FIG. 6.

Next, fluorine diffusion toward the passivation film 42 is explained. Since the passivation film 42 has the thick thickness of 550 nm, fluorine is prevented from diffusing from the intervening film 41 towards the passivation film 41, as indicated by an arrow 56 shown in FIG. 6. For this reason, fluorine included in the intervening film 41 mainly diffuses toward the interfacial surface of the silicon substrate 1. Thus, the support film 23, the cylinder stopper film 19, and the passivation film 42 do not work as barriers against fluorine diffusion toward the interfacial surface of the silicon substrate 1.

Even if the low-dielectric constant films 30 and 34 and the inter-layer insulating film 38 are SiCO films or silicon oxide films, which are free of fluorine, fluorine can diffuse from the intervening film 41 toward the interfacial surface of silicon substrate 1, thereby enabling termination of dangling bonds.

In this case, fluorine partially remains in the inter-layer insulating film free of fluorine, which is disposed between the intervening film 41 and the silicon substrate 1. However, the fluorine remaining in the SiCO film does not cause a decrease in the dielectric constant of the SiCO film. On the other hand, fluorine remaining in the silicon oxide film is expected to cause a decrease in the dielectric constant.

Even if at least one of the low-dielectric constant films 30 and 34 and the inter-layer insulating film 38 is a SiOF film, the content rate of fluorine is limited to such an extent that a film is not peeled. For this reason, termination of dangling bonds caused by fluorine diffusion from the SiOF film is not achieved. Therefore, fluorine diffusing from the intervening film 41 reacts with the interfacial surface of the silicon substrate 1, and thereby terminates dangling bonds.

The above thermal treatment is carried out at least after the intervening film 41 is formed. In other words, as long as the intervening film 41 is formed first, the thermal treatment may be carried out before or after the passivation film 42 is formed.

Even if dangling bonds on the interfacial surface of the silicon substrate 1 are terminated, dangling bonds occur at a portion where silicon-fluorine bond is weak during a subsequent thermal treatment. For this reason, the dangling-bond termination process, i.e., the thermal treatment is preferably carried out after the process of forming the passivation film 42, which is the final process in which the heating temperature is in the allowable range. However, a dangling-bond termination process after the intervening film 41 is also effective. Therefore, the thermal treatment may be carried out after formation of the intervening film 41 and after formation of the passivation film 42.

If the thermal treatment is carried out after formation of the passivation film 42, the thermal treatment is preferably carried out in a hydrogen atmosphere. The passivation film 42 contains hydrogen by approximately 1×10¹⁹ atoms/cm³. Therefore, a thermal treatment in a hydrogen atmosphere prevents hydrogen from escaping from the passivation film 42. Further, hydrogen diffuses from the passivation film 42 and reacts with the interfacial surface of the silicon substrate 1, thereby terminates dangling bonds. Accordingly, the synergistic effect of hydrogen and fluorine termination of dangling bonds can be achieved.

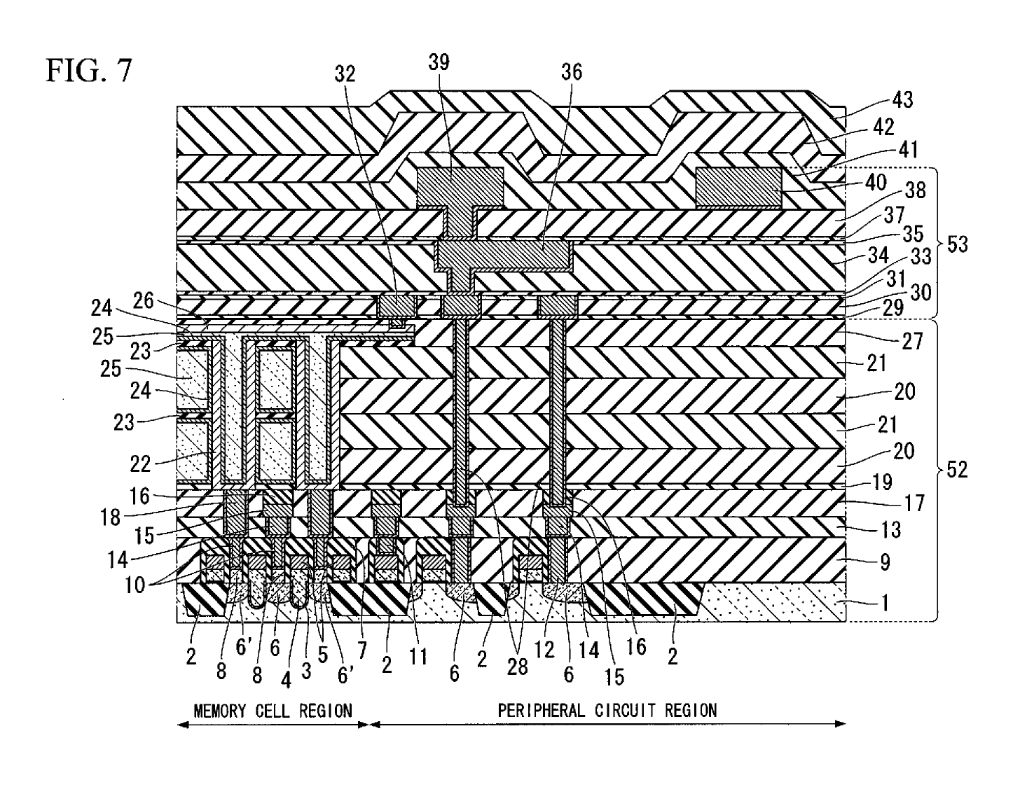

Then, a cap-film forming process, a bonding-hole forming process, and an assembling process are sequentially carried out. In the cap-film forming process, the cap film 43 is formed over the passivation film 42, as shown in FIG. 7. Specifically, a solution in which polyimide is melted is applied over the passivation film 42, and then is cured at a temperature of, for example, 200° C. to 300° C., for approximately 30 minutes. The polyimide forming the cap film 43 is thermally decomposed if heated up to a temperature of 500° C. or more. For this reason, the thermal treatment for diffusing the aforementioned fluorine is carried out before the cap film 43 is formed.

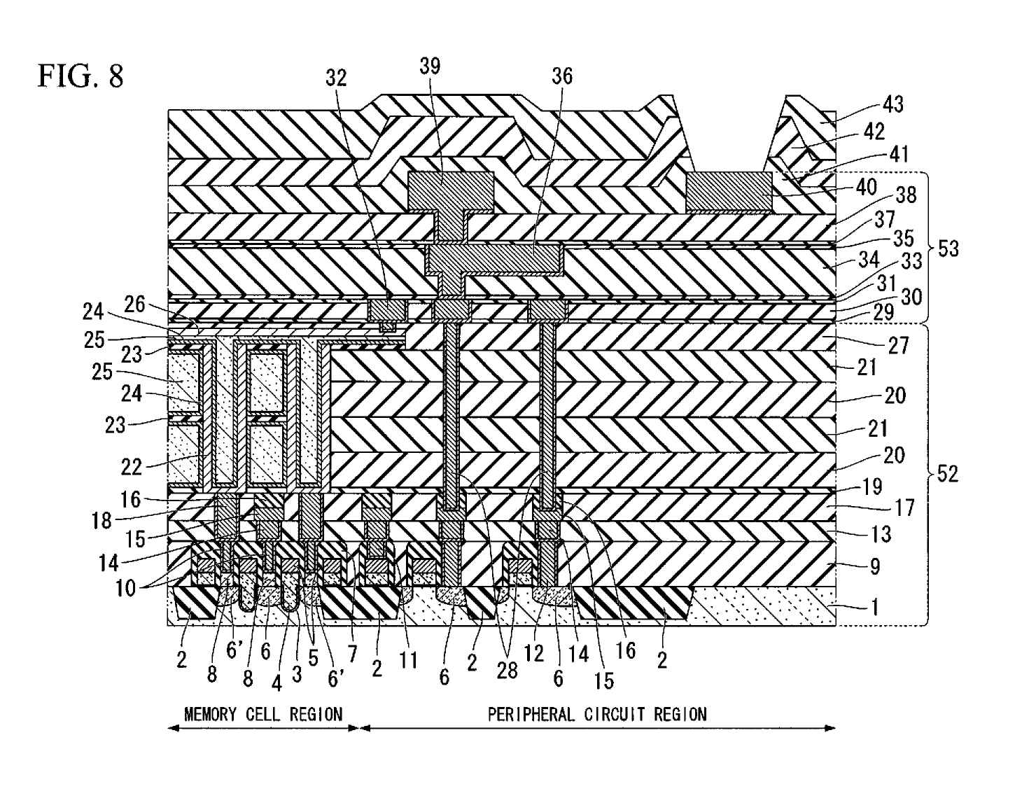

In the bonding-hole forming process, holes are formed by photolithography and dry etching so as to penetrate the intervening film 41, the passivation film 42, and the cap film 43, which cover the bonding pad 40, and to expose an upper surface of the bonding pad 40, as shown in FIG. 8.

In the assembling process, a wafer is diced into chip pieces, and the bonding wire 44 is connected to the exposed bonding pad 40. Thus, the chip is electrically connected to an external terminal included in a package through the bonding wire 44. In this manner, the DRAM 51 of the first embodiment is manufactured.

According to the DRAM 51 of the first embodiment, the intervening film 41 containing fluorine is disposed between the third wiring 39 and the passivation film 42. For this reason, fluorine can diffuse from the intervening film 41 toward the interfacial surface of the silicon substrate 1, and thereby terminate dangling bonds on the interfacial surface of the silicon substrate 1. Accordingly, the DRAM 51 achieving a reduction in leak current and an enhancement in refresh characteristics, can be achieved.

Additionally, even if a fluorine-containing insulating film is not used as inter-wiring-layers included in the multi-layered wiring layer 53, fluorine can diffuse from the intervening film 41 toward the interfacial surface of the silicon substrate 1. For this reason, a carbon-containing silicon oxide film having better characteristics of a dielectric constant or the like than that of a fluorine-containing inter-layer insulating film can be used as the inter-wiring-layer insulating film. Accordingly, the dielectric constant of the insulating film can be further reduced, and therefore the DRAM 51 achieving a reduction in a capacity between wirings can be provided.

According to the method of manufacturing the DRAM (semiconductor device) 51 of the first embodiment, a thermal treatment is carried out after the intervening film 41 containing fluorine is formed. Accordingly, fluorine can diffuse from the intervening film 41 toward the interfacial surface of the silicon substrate 1.

Additionally, an insulating film free of fluorine (such as a carbon-containing silicon oxide film) can be used as the inter-layer insulating film. Even in this case, fluorine is included in the insulating film in the end. However, the initial characteristics of the insulating film do not degrade. If a normal silicon oxide film is used as the inter-layer insulating film, fluorine diffusion toward the inter-layer insulating film can achieve a decrease in the dielectric constant.

Further, a fluorine-containing film can be used as the inter-layer insulating film included in the multi-layered wiring structure. The content rate of fluorine included in the fluorine-containing film used as the inter-layer insulating film is limited, and therefore fluorine diffusion from the fluorine-containing film cannot achieve the effect of terminating dangling bonds. However, the fluorine-containing intervening film 41 is disposed over the uppermost third wiring 39 in the present embodiment. Accordingly, even if the content rate of fluorine included in the inter-layer insulating film is limited, fluorine diffusion from the intervening film 41 can achieve termination of dangling bonds on the interfacial surface of the silicon substrate 1.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percent of the modified term if this deviation would not negate the meaning of the word it modifies.

It is apparent that the present invention is not limited to the above embodiments, but may be modified and changed without departing from the scope and spirit of the invention.

What is claimed is:

1. A semiconductor device comprising:
a first multi-layered structure;
a first insulating film over the first multi-layered structure, the first insulating film containing fluorine; and
a second insulating film over the first insulating film.

2. The semiconductor device according to claim 1, wherein the second insulating film has a barrier performance against fluorine diffusion.

3. The semiconductor device according to claim 1, wherein the second insulating film contains hydrogen.

4. The semiconductor device according to claim 1, further comprising:
a second multi-layered structure below the first multi-layered structure, the second multi-layered structure comprising a first group of inter-layer insulating films,
wherein the first multi-layered structure comprises a second group of inter-layer insulating films being smaller in dielectric constant than the first group of inter-layer insulating films.

5. The semiconductor device according to claim 4, wherein the second group of inter-layer insulating films is below the first insulating film.

6. The semiconductor device according to claim 1, wherein the first insulating film contains fluorine in the range of 1×10¹⁸ atoms/cm³ to 1×10²⁰ atoms/cm³.

7. The semiconductor device according to claim 1, wherein the second insulating film contains hydrogen in the range of 1×10¹⁸ atoms/cm³ to 1×10²⁰ atoms/cm³.

8. The semiconductor device according to claim 1, wherein the first multi-layered structure is free of fluorine.

9. The semiconductor device according to claim 8, wherein the first multi-layered structure comprises a low-k film.

10. The semiconductor device according to claim 1, wherein the first multi-layered structure comprises an inter-layer insulating film containing fluorine.

11. The semiconductor device according to claim 1, wherein the first multi-layered structure comprises a plurality of wiring layers.

12. The semiconductor device according to claim 4, wherein the second multi-layered structure comprises a plurality of memory cells.

13. The semiconductor device according to claim 4, wherein the second multi-layered structure comprises:
a plurality of electrodes;
a plurality of support films each mechanically supporting adjacent two of the plurality of electrodes.

14. The semiconductor device according to claim 13, wherein
the plurality of electrodes are aligned in a plurality of lines, and
each of the plurality of support films is disposed between adjacent two of the plurality of lines.

15. A semiconductor device comprising:
a substrate;
a first multi-layered structure over the substrate;
a second multi-layered structure over the first multi-layered structure, the second multi-layered structure comprising a fluorine-containing insulating film and a barrier film over the fluorine-containing insulating film.

16. The semiconductor device according to claim 15, wherein the first multi-layered structure comprises a plurality of memory cells.

17. The semiconductor device according to claim 15, wherein the second multi-layered structure comprises a plurality of wiring layers.

18. A method of manufacturing a semiconductor device, comprising:
forming a first multi-layered structure over a substrate;
forming a second multi-layered structure over the first multi-layered structure, the second multi-layered structure comprising an insulating film and a barrier film over the insulating film, the insulating film containing fluorine; and
diffusing fluorine from the insulating film toward the substrate to terminate dangling bonds on the substrate.

19. The method according to claim 18, further comprising:
performing a thermal treatment after at least one of the insulating film and the barrier film is formed.

20. The method according to claim 19, wherein the thermal treatment is performed in a hydrogen atmosphere.
